(19) United States
(12) Patent Application Publication
(10) Pub. No.: US 2026/0276711 A1
(43) Pub. Date: Sep. 17, 2026

(54) EIS MEASUREMENT FOR BATTERIES UNDER LOAD WITH STORED BATTERY MODEL

(71) Applicant: Analog Devices, Inc., Wilmington, MA (US)

(72) Inventors: Srilakshmi Pattabiraman, Revere, MA (US); Frank M. Yaul, Cambridge, MA (US); Ravi Kiran Raman, Belmont, MA (US); Omer Tanovic, Acton, MA (US)

(21) Appl. No.: 19/080,396

(22) Filed: Mar. 14, 2025

(51) Int. Cl. G01R 31/367; G01R 31/374; G01R 31/385; G01R 31/389

(52) U.S. Cl. CPC G01R 31/367; G01R 31/374; G01R 31/385; G01R 31/389

(57) ABSTRACT

Various examples are directed to systems and methods for operating a battery. An Electrochemical Impedance Spectroscopy (EIS) circuit may apply an alternating current (AC) excitation signal to a battery at a first time while the battery is also under a load and measure a first impedance of the battery at a first time. The EIS circuit may determine at least one condition of the battery at the first time, the at least one condition comprising a load current of the battery and generate an expected impedance of the battery at the first time using a stored battery model and the at least one condition of the battery at the first time. The EIS circuit May determine that the first impedance of the battery is an outlier based on a difference between the first impedance of the battery and the expected impedance of the battery.

### FIELD OF THE DISCLOSURE

The present disclosure generally relates to electronics, and more particularly to systems and methods for performing electrochemical impedance spectroscopy measurements of a battery such as, for example, a battery under load.

### BACKGROUND

Electrochemical Impedance Spectroscopy (EIS) is a diagnostic technique used to characterize the properties of electrochemical devices such as, for example, batteries. When used with a battery, EIS involves applying an alternating current (AC) excitation signal to the battery. The excitation signal may be applied over a range of frequencies. The response of the battery may be measured at each respective frequency to determine an impedance of the battery corresponding to each respective frequency. The resulting impedance data can be used for determining various parameters related to the state of the battery.

### SUMMARY

Example 1 is an Electrochemical Impedance Spectroscopy (EIS) circuit comprising: an excitation circuit for generating an alternating current (AC) excitation signal; and a control circuit configured to perform operations comprising: applying an alternating current (AC) excitation signal to a battery at a first time while the battery is also under a load; measuring a first impedance of the battery at a first time; determining at least one condition of the battery at the first time, the at least one condition comprising a load current of the battery; generating an expected impedance of the battery at the first time using a stored battery model and the at least one condition of the battery at the first time; determining that the first impedance of the battery is an outlier, the determining based on a difference between the first impedance of the battery and the expected impedance of the battery; and based on determining that the first impedance is an outlier, measuring an additional impedance of the battery.

In Example 2, the subject matter of Example 1 optionally includes the load current being a positive load current provided by the battery to the load.

In Example 3, the subject matter of any one or more of Examples 1-2 optionally includes the load current being a negative load current provided to the battery by the load.

In Example 4, the subject matter of any one or more of Examples 1-3 optionally includes the at least one condition further comprising a cell temperature.

In Example 5, the subject matter of any one or more of Examples 1~4 optionally includes the stored battery model comprising a regression model generated using at least one reference battery different than the battery, the generating of the expected impedance comprising executing the regression model using the at least one condition of the battery at the first time.

In Example 6, the subject matter of any one or more of Examples 1-5 optionally includes the stored battery model comprising an equivalent circuit model (ECM), the generating of the expected impedance comprising solving the ECM using the at least one condition at the battery of the first time.

In Example 7, the subject matter of any one or more of Examples 1-6 optionally includes the stored battery model comprising an equivalent circuit model (ECM), the generating of the expected impedance comprising: accessing equivalent circuit parameter data, the equivalent circuit parameter data describing a set of circuit parameters corresponding to the at least one condition of the battery at the first time; and generating the expected impedance of the battery at the first time at least in part by applying the set of circuit parameters to the ECM.

In Example 8, the subject matter of any one or more of Examples 1-7 optionally includes the generating of the expected impedance comprising: using the at least one condition of the battery at the first time to select an ECM from a set of ECMs; using the at least one condition of the battery to select a set of circuit parameters; and generating the expected impedance of the battery at the first time at least in part by applying the set of circuit parameters to the selected ECM.

Example 9 is a method of analyzing a battery comprising: applying an alternating current (AC) excitation signal to a battery at a first time while the battery is also under a load; measuring a first impedance of the battery at a first time; determining at least one condition of the battery at the first time, the at least one condition comprising a load current of the battery; generating an expected impedance of the battery at the first time using a stored battery model and the at least one condition of the battery at the first time; determining that the first impedance of the battery is an outlier, the determining based on a difference between the first impedance of the battery and the expected impedance of the battery; and based on determining that the first impedance is an outlier, measuring an additional impedance of the battery.

In Example 10, the subject matter of Example 9 optionally includes the load current being a positive load current provided by the battery to the load.

In Example 11, the subject matter of any one or more of Examples 9-10 optionally includes the load current being a negative load current provided to the battery by the load.

In Example 12, the subject matter of any one or more of Examples 9-11 optionally includes the at least one condition further comprising a cell temperature.

In Example 13, the subject matter of any one or more of Examples 9-12 optionally includes the stored battery model comprising a regression model generated using at least one reference battery different than the battery, the generating of the expected impedance comprising executing the regression model using the at least one condition of the battery at the first time.

In Example 14, the subject matter of any one or more of Examples 9-13 optionally includes the stored battery model comprising an equivalent circuit model (ECM), the generating of the expected impedance comprising solving the ECM using the at least one condition at the battery of the first time.

In Example 15, the subject matter of any one or more of Examples 9-14 optionally includes the stored battery model comprising an equivalent circuit model (ECM), the generating of the expected impedance comprising: accessing equivalent circuit parameter data, the equivalent circuit parameter data describing a set of circuit parameters corresponding to the at least one condition of the battery at the first time; and generating the expected impedance of the battery at the first time at least in part by applying the set of circuit parameters to the ECM.

In Example 16, the subject matter of any one or more of Examples 9-15 optionally includes the generating of the expected impedance comprising: using the at least one condition of the battery at the first time to select an ECM from a set of ECMs; using the at least one condition of the battery to select a set of circuit parameters; and generating the expected impedance of the battery at the first time at least in part by applying the set of circuit parameters to the selected ECM.

Example 17 is a non-transitory computer-readable medium comprising instructions thereon that, when executed by at least one processor, cause the at least one processor to perform operations comprising: applying an alternating current (AC) excitation signal to a battery at a first time while the battery is also under a load; measuring a first impedance of the battery at a first time; determining at least one condition of the battery at the first time, the at least one condition comprising a load current of the battery; generating an expected impedance of the battery at the first time using a stored battery model and the at least one condition of the battery at the first time; determining that the first impedance of the battery is an outlier, the determining based on a difference between the first impedance of the battery and the expected impedance of the battery; and based on determining that the first impedance is an outlier, measuring an additional impedance of the battery.

In Example 18, the subject matter of Example 17 optionally includes the load current being a positive load current provided by the battery to the load.

In Example 19, the subject matter of any one or more of Examples 17-18 optionally includes the load current being a negative load current provided to the battery by the load.

In Example 20, the subject matter of any one or more of Examples 17-19 optionally includes the at least one condition further comprising a cell temperature.

### BRIEF DESCRIPTION OF THE DRAWINGS

FIG. 1 is a diagram showing one example of an environment including a battery, a load, and an EIS circuit.

FIG. 2 is a diagram showing another example of the environment of FIG. 1 with the control circuit configured to consider real and imaginary component of the measured battery impedances separately.

FIG. 3 is a flowchart showing one example of a process flow that may be executed by the EIS circuit in the environment of FIGS. 1 and 2 to perform an EIS analysis of the battery.

FIG. 4 is a flowchart showing another example of a process flow that may be executed by the EIS circuit in the environment of FIG. 1 or FIG. 2 to perform an EIS analysis of the battery.

FIG. 5 is a diagram showing an example of the environment comprising an EIS circuit, a battery, and a load, where the EIS circuit is configured to implement outlier detection using a stored model.

FIG. 6 is a flowchart showing one example of a process flow that may be executed by the EIS circuit in the environment of FIG. 5 to perform an EIS analysis of the battery.

FIG. 7 is a flowchart showing one example of a process flow that may be executed by the EIS circuit to determine an expected impedance using an Equivalent Circuit Model (ECM).

FIG. 8 is a diagram showing an example of the environment comprising an EIS circuit, a battery, and a load, where the EIS circuit is configured to implement outlier detection using a multivariable probability distribution.

FIG. 9 is a flowchart showing one example of a process flow that may be executed by the EIS circuit in the environment of FIG. 8 to perform an EIS analysis of the battery.

FIG. 10 is a diagram showing another example of the environment of FIG. 8 with the EIS circuit in communication with a remote computing system.

FIG. 11 is a flowchart showing one example of a process flow that may be executed by the EIS circuit of FIGS. 8 and 10 and/or the remote computing system of FIG. 10 to generate the multivariable probability distribution.

FIG. 12 is a block diagram of an example machine upon which any one or more of the techniques (e.g., methodologies) discussed herein may be performed.

### DESCRIPTION

Using EIS to monitor a battery can provide significant insight into the state and behavior of the battery. This can include information about the state of charge of the battery as well as information about properties of the battery that can indicate battery damage or degradation

Battery EIS may be performed by providing an alternating current (AC) excitation signal that is small relative to the load current of the battery to avoid unduly perturbing the battery and/or driving the battery into nonlinear operation. For example, the excitation signal for battery EIS may have an amplitude of a few milliamps and be applied for a time period of between about a few hundred milliseconds and a few seconds, depending on the frequency being measured. The battery load current, on the other hand, may be significantly larger. For example, in some applications, the battery current may be tens or even hundreds of amps. Changes in the battery current within the time period that an EIS excitation signal is applied can also be quite large, for example, measured in tens or hundreds of amps.

Outlier impedance measurements, also referred to herein as outliers, occur when an EIS impedance measurement of a battery changes in a manner that makes it unrepresentative of the state of the battery. Outliers can have various causes. For example, changes in battery load current can introduce transients that are large enough relative to the size of the excitation signal to materially affect the measured impedance of the battery. Also, for example, the battery's load may introduce harmonic content that also skews the battery impedance measured during EIS. For example, when the battery is charging, the charger may introduce harmonic content that affects the measured battery impedance.

Various example techniques are used to detect outliers in battery EIS. For example, some techniques involve generating detailed models of battery behavior. EIS measurements are compared to the detailed models to detect outliers. Detailed models, however, may utilize significant memory and/or processing resources to implement. Also, some example techniques may generate false positives as the load current of the battery changes. That is, a battery impedance measurement may be mistakenly indicated to be an outlier. This may result in the unnecessary repetition of battery impedance measurements. Also, accounting for changes in load current may require still more detailed models, exacerbating memory and processor resource usage.

Various examples described herein address these and other challenges utilizing systems and methods for implementing battery EIS using distribution characteristics of a set of measured battery impedance measurements. In some examples, a distribution characteristic may be determined based on the set of measured battery impedances. The set of measured battery impedances may include battery impedances measured during an EIS process. For example, the set of measured battery impedances may be measured in response to an excitation signal provided to the battery over a range of frequencies. In some examples, the set of measured battery impedances includes a moving window of the last N impedance measurements taken, where N may be between about 5 and 20. In some examples, N may be 10. In some examples, the set of measured battery impedances may be measured while the battery is under load.

The distribution characteristic may describe a distribution of the set of measured battery impedances. For example, the distribution characteristic may be or include a mean of the set of measured battery impedances, a standard deviation of the set of measured battery impedances, and/or the like. A new battery impedance may be measured and compared to the distribution characteristic to determine whether the new battery impedance is an outlier. For example, if the distribution characteristic is a mean, the new battery impedance may be considered an outlier if it deviates from the mean by more than a threshold amount. In some examples, the threshold amount is a multiple of a standard deviation of the distribution.

In some examples, the distribution characteristic may be determined based on a weighting of the set of measured battery impedances. Weights may be selected, for example, to emphasize more recently measured battery impedances over older measured battery impedances. For example, battery impedances of the set of measured battery impedances closer in time to the new battery impedance may receive a higher weight than battery impedances farther in time from the new battery impedance.

In various examples, outlier detection, as described herein, may be advantageously performed based on a single measured battery impedance. For example, the new measured battery impedance may be compared to the distribution characteristic and an EIS circuit may determine whether the new measured battery impedance is an outlier without waiting for additional new measured battery impedances. Also, in some examples, outlier detection as described herein may operate without making explicit modifications to a battery model to account for changes in load current to the battery.

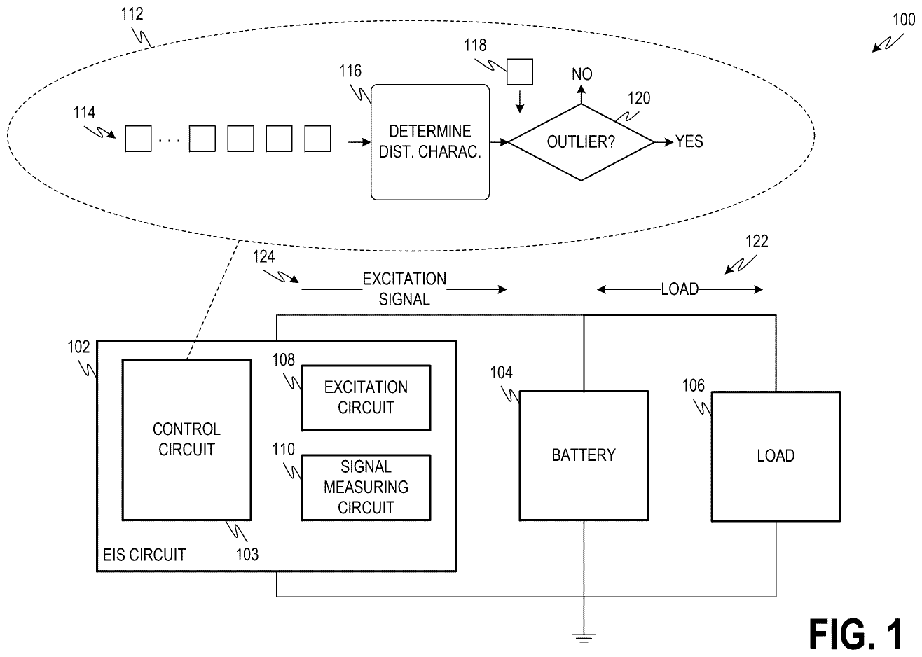

FIG. 1 is a diagram showing one example of an environment 100 including a battery 104, a load 106, and an EIS circuit 102. The battery 104 may be any suitable type of battery such as, for example, a lithium-ion battery, a lead-acid battery, a nickel-metal hydride battery, a nickel-cadmium battery, and alkaline battery, a lithium iron phosphate battery, and/or the like.

The battery 104 is electrically coupled to the load 106. The load 106 may be positive or negative. The load 106 is a positive load when it draws power from the battery 104. Examples of positive loads include electric motors, portable electronic devices such as smartphones, laptops, tablet computing devices, and/or the like. The load 106 is a negative load 106 when it provides power to the battery. A battery charger is an example of a negative load.

The load 106 may provide a load current 122. The load current 122 may flow between the battery 104 and the load 106. The load current 122 may be a positive current (e.g., directed towards the load 106) when the load 106 is a positive load and may be a negative current (e.g., directed towards the battery 104) when the load 106 is a negative load.

The EIS circuit 102 may also be electrically coupled to the battery 104 to provide an excitation signal 124 to the battery 104. The EIS circuit 102 may be or comprise various different hardware component such as, for example, one or more microprocessors, one or more field programmable gate arrays (FPGAs), one or more application specific integrated circuits (ASICs) and/or the like. The EIS circuit 102 may be arranged in any suitable form such as, for example, on an application-specific integrated circuit (ASIC), a field-programmable gate array (FPGA), and/or the like. The EIS circuit 102 may comprise a control circuit 103, an excitation circuit 108, and a signal measuring circuit 110.

The excitation circuit 108 may generate the excitation signal 124, which may be an AC signal. The excitation circuit 108 may comprise various components for generating a time-varying signal such as, for example, one or more oscillators, one or more phase-locked loop circuits, one or more amplifiers, and/or the like. The excitation circuit may generate the excitation signal 124 to sweep a frequency range. The frequency range may be from about 1 Hz to about 100 Hz. In some examples, the excitation circuit 108 is configured to generate the excitation signal 124 to sweep the frequency range in discrete increments. In some examples, the excitation circuit 108 is configured to generate the excitation signal in increments of between about 5 Hz and about 10 Hz.

The signal measuring circuit 110 may measure a value of the excitation signal 124 to determine one or more impedances of the battery 104, also referred to herein as battery impedances. For example, the excitation circuit 108 may generate the excitation signal 124 at the signal measuring circuit 110 may measure a current of the excitation signal 124. The signal measuring circuit 110 may comprise various components for measuring the current and/or voltage of the excitation signal 124 such as, for example, various amplifiers, analog-to-digital converters, and/or the like.

The control circuit 103 may comprise electronic components for controlling the operation of the EIS circuit 802. For example, the control circuit 103 may comprise one or more microprocessors, one or more logic gates, one or more logic gate-implemented state machines, and/or the like. The control circuit 103 may direct the operation of the excitation circuit 108 and signal measuring circuit 110. For example, the control circuit 103 may direct the excitation circuit 108 to provide the excitation signal 124. The control circuit 13 may also direct the signal measuring circuit 110 to measure the value of the excitation signal, as described herein. The control circuit 103 may also be configured to detect outliers, for example, as described herein. The control circuit 103 may comprise any suitable processing hardware such as, for example, one or more processors, one or more gate-based state machines, one or more field programmable gate arrays and/or the like.

In some examples, the control circuit 103 instructs the excitation circuit 108 to begin generating the excitation signal 124, for example, with a time-varying voltage that sweeps the frequency range. For example, the excitation circuit 108 may hold the excitation signal 124 at a first frequency of the frequency range. While the excitation circuit 108 holds the excitation signal 124 at the first frequency of the frequency range, the signal measuring circuit 110 may measure a current of the excitation signal 124. The excitation circuit 108 may then generate the excitation signal 124 at a second frequency of the frequency range. While the excitation circuit 108 generates the excitation signal 124 at the second frequency, the signal measuring circuit 110 may measure the current of the excitation signal 124 at the second frequency. The current measurements may be provided to the control circuit 103.

The control circuit 103 may receive current measurements, or other measurements of the excitation signal 124 and determine the corresponding impedances of the battery. The measured impedances of the battery 104 across the frequency range may be used to monitor the battery 104, for example, as described herein.

The control circuit 102 may be configured to detect outliers. For example, the control circuit 102 may be configured to analyze each measured impedance of the battery to determine whether the measured impedance is an outlier. Window 112 shows an example workflow for detecting outliers. The window 112 shows a set 114 of measured battery impedances of the battery one of four. The set 114 of measured battery impedances may have been sequentially measured, for example, in the order shown in FIG. 1.

The set 114 of measured battery impedances may be input to a distribution characteristic operation 116. At the operation 116, the control circuit 103 may determine a distribution characteristic of the set 114 of measured battery impedances. The distribution characteristic is a characteristic of a distribution describing the set 114 of measured battery impedances. Any suitable distribution may be used including, for example, a normal distribution, a Gaussian distribution, a uniform distribution, a Clipped/Quantized distribution, and/or the like. The distribution characteristic may be, for example, a mean of the set 114 of measured battery impedances, a standard deviation of the set 114 of measured battery impedances, and/or the like. In examples where the distribution characteristic is a mean or average of the set 114 of measured battery impedances, the mean may be a moving average of measured battery impedances.

A new impedance 118 may be measured as described herein. At operation 120, the control circuit 103 may determine whether the new impedance is an outlier. The control circuit 103 may compare the new impedance 118 to the distribution characteristic determined at operation 116. If the new impedance differs or deviates from the distribution characteristic by more than a threshold amount, the new impedance 118 is determined to be an outlier.

Consider an example in which the distribution of the set 114 of measured battery impedances is consistent with a normal distribution and the distribution characteristic is a mean of the set 114 of battery impedances. In this example, if the new impedance 118 deviates from the mean of the set 114 of battery impedances by more than a threshold value, then the new impedance 118 is determined to be an outlier. In the example of FIG. 1, the control circuit 103 may consider the real and reactive or imaginary component of the battery impedances together or separately. For example, the set 114 of measured battery impedances may consist of real components of measured battery impedances only, imaginary component of measured battery impedances only, or impedance magnitudes only. The new impedance 118 may be considered in a manner consistent with the form of the set 114 of measured battery impedances. For example, if the set 114 of measured battery impedances comprises real components, a real component of the new impedance 118 may be considered. If the set 114 of measured battery impedances comprises imaginary component, and imaginary component of the new impedance 118 may be considered. If the set 114 of measured battery impedances comprises magnitudes, that a magnitude of the impedance 118 may be considered.

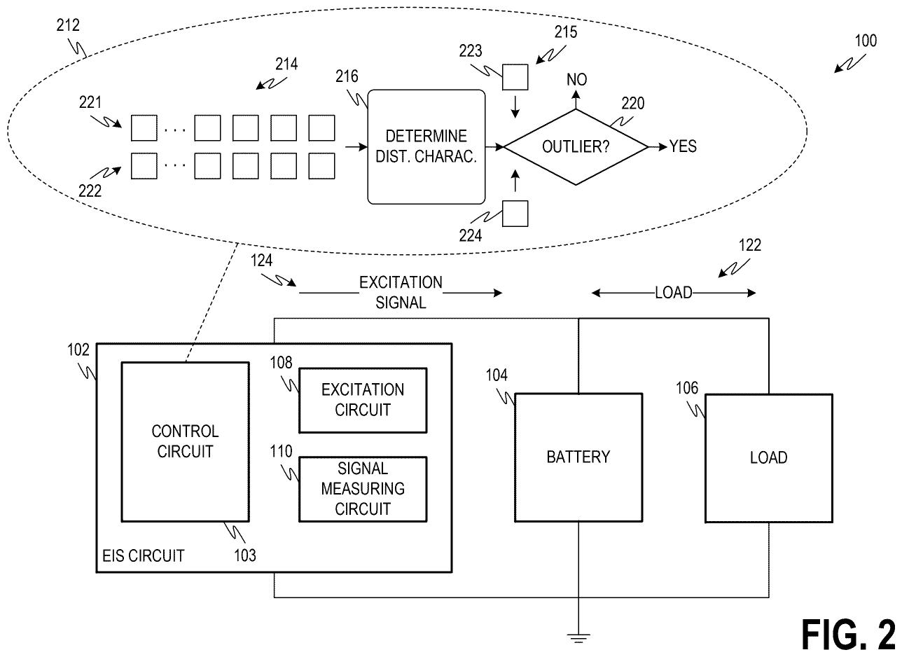

In some examples, the control circuit 103 may be programmed to consider the real and the imaginary component of measured battery impedances separately. FIG. 2 is a diagram showing another example of the environment 100 with the control circuit 103 configured to consider real and imaginary component of the measured battery impedances separately. At window 212, FIG. 2 shows a set 214 of measured battery impedances. Each battery impedance of the set 214 of measured battery impedances comprises a real component and an imaginary component. This results in a set 221 of real component of the measured battery impedances and a set 222 of imaginary components of the measured battery impedances.

At operation 216, the control circuit 103 may determine respective distribution characteristics for the set 221 of real components of the measured battery impedances and the set 222 of imaginary components of the measured battery impedances. This may result in, for example, one or more distribution characteristics describing the set 221 of real components of the measured battery impedances and one or more distribution characteristics describing the set 222 of imaginary components of the measured battery impedances.

A new measured battery impedance 215 may comprise a real component 223 and an imaginary component 224. At operation 220, the control circuit 103 may compare the real component 223 to the determined distribution characteristic of the set 221 of real components of the measured battery impedances and the imaginary component 224 to the determined distribution characteristic of the set 222 of imaginary components of the measured battery impedances. The new measured battery impedance 215 may be an outlier if either the real component 223 or the imaginary component 224 differ from their respective distribution characteristics by more than a threshold amount.

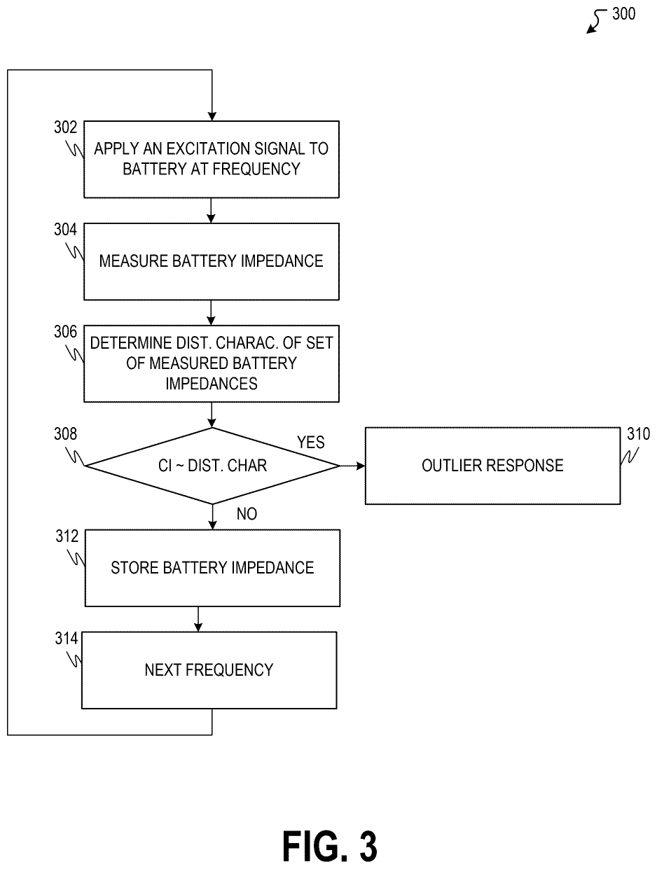

FIG. 3 is a flowchart showing one example of a process flow 300 that may be executed by the EIS circuit 102 in the environment 100 of FIG. 1 or FIG. 2 to perform an EIS analysis of the battery 104. At operation 302, the EIS circuit 102 may apply the excitation signal 124 to the battery 104 at a first frequency. At operation 304, the EIS circuit 102 may measure the impedance of the battery 104 based on the excitation signal applied at operation 302. This may include, for example, measuring a current of the excitation signal 124 at the first frequency.

At operation 306, the EIS circuit 102 may determine a distribution characteristic of a set of battery impedances. This may be, for example, a mean, a standard deviation, and/or the like as described herein. The set of battery impedances may include the N most recently measured battery impedances, for example, as described herein. In some examples, the EIS circuit 102 may generate two distribution characteristics based on the battery impedance measured at operation 304, for example, as described with respect to FIG. 2. For example, a first distribution characteristic may be based on the real component of the battery impedance measured at operation 304 and a second distribution characteristic may be based on the imaginary component of the battery impedance measured at operation 304.

At operation 308, the EIS circuit 102 may determine if the battery impedance measured at operation 304 is within a threshold of the distribution characteristic of the set of measured battery impedances determined at operation 306. In examples where the EIS circuit 102 generated a distribution characteristic for the real component and a distribution characteristic for the imaginary component, two comparisons may take place. The first comparison may be between the real component of the battery impedance measured at operation 304 and the real component distribution characteristic. A second comparison may be between the imaginary component of the battery impedance measured at operation 304 and the imaginary component distribution characteristic.

If the battery impedance measured at operation 304 deviates from the distribution characteristic by more than a threshold amount, then the battery impedance measured at operation 304 is determined to be an outlier. In examples similar to FIG. 2, the battery impedance measured at operation 304 may be considered an outlier if its real component differs from a real component distribution characteristic by more than a threshold or if its imaginary component differs from an imaginary component distribution characteristic by more than a threshold. In some examples, the threshold or threshold may be multiples of a standard deviation of a distribution describing the set of measured battery impedances. In some examples, the threshold may be between about 1 standard deviation and about 3 standard deviations. For example, the threshold may be 1 standard deviation, 1.5 standard deviations, 2 standard deviations, 2.5 standard deviations, 3 standard deviations, and/or the like. In some examples, the threshold used for the real component of the battery impedance may be different than the threshold used for the imaginary component of the battery impedance. For example, the threshold for the real component of the battery impedance may be based on a standard deviation of the real components of the set of measured battery impedances. The threshold for the imaginary component of the battery impedance may be based on a standard deviation of the imaginary components of the set of measured battery impedances.

If the battery impedance measured at operation 304 is within the threshold of the distribution characteristic measured at operation 306, then, at operation 312, the EIS circuit 103 may store the battery impedance measured at operation 304. For example, the battery impedance measured at operation 304 may be stored for use in determining distribution characteristics for the analysis of future measured battery impedances. In examples such as the example of FIG. 2 where the real and imaginary component of the measured battery impedance are considered separately, the battery impedance measured at operation 304 may be considered within the threshold of the distribution characteristic measured at operation 306 when both the imaginary component of the measured battery impedance is within a threshold of the distribution characteristic of the imaginary components of the set of measured battery impedances and the real component of the measured battery impedance is within a threshold of the distribution characteristic of the real component of the set of measured battery impedances. At operation 314, the EIS circuit 102 may move to the next frequency and return to operation 302 to apply the excitation signal 124 at the next frequency.

If the battery impedance measured at operation 304 is not within the threshold of the distribution characteristic measured at operation 306, then, at operation 310, the EIS circuit 102 may execute an outlier response. The outlier response may include repeating some or all of the EIS evaluation of the battery 104. In some examples, repeating some or all of the EIS evaluation of the battery 104 includes returning to operation 302 and reapplying the excitation signal at the same frequency. In some examples, repeating some or all of the EIS evaluation of the battery 104 includes remeasuring battery impedances across multiple excitation signal frequencies.

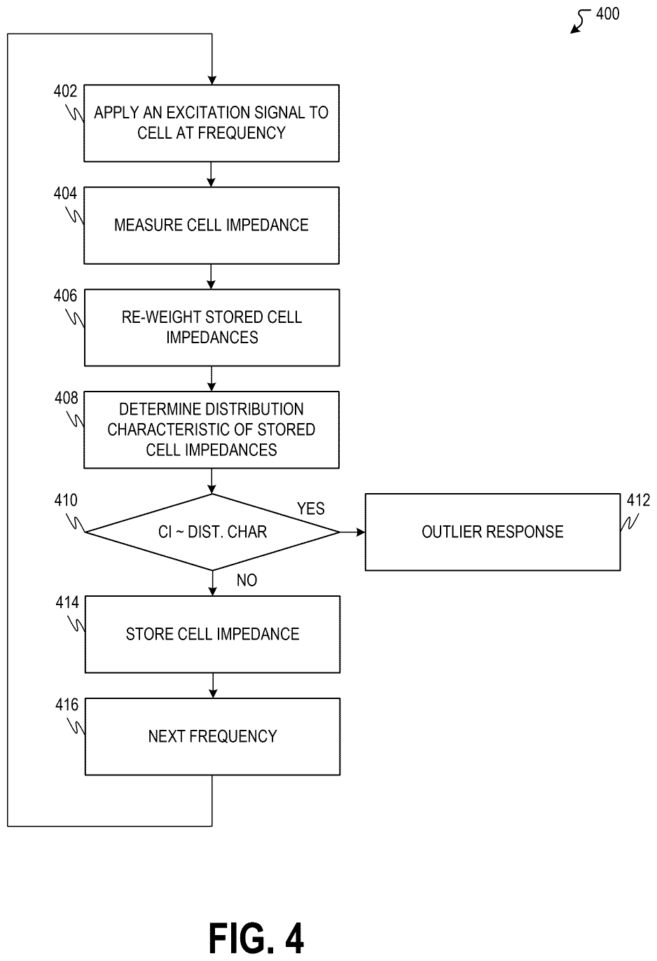

FIG. 4 is a flowchart showing another example of a process flow 400 that may be executed by the EIS circuit 102 in the environment 100 of FIG. 1 or FIG. 2 to perform an EIS analysis of the battery 104. In the example of FIG. 4, the set of measured battery impedances is weighted based on when the measured battery impedances were taken.

At operation 402, the EIS circuit 102 may apply the excitation signal 124 to the battery 104 at a first frequency. At operation 404, the EIS circuit 102 may measure the impedance of the battery 104 based on the excitation signal applied at operation 402. This may include, for example, measuring a current of the excitation signal 124 at the first frequency.

At operation 406, the EIS circuit 102 may apply weights to the set of measured battery impedances. The set of measured battery impedances may be weighted based on when the respective battery impedances were measured.

The weights assigned to different battery impedances may reflect the relevance of the respective battery impedances to whether the current battery impedance is an outlier. In some examples, the weight for prospective battery impedances may be based on how much time has passed since the battery impedance was measured or similar quantity such as, for example, how many other battery impedances have been measured since the respective battery impedances were measured. Consider the example Weight Vector [1] below:

$$WV = [ 1 / 5 , 1 / 4 , 1 / 3 , 1 / 2 , 1 / 1 ] \qquad [ 1 ]$$

The example Weight Vector [1] may be applied to a set of five previously measured battery impedances such that the most recently measured battery impedance is weighted by 1/1, the next most recently measured battery impedance is weighted by 1/2, the next most recently measured battery impedance is weighted by 1/3, and so on. Although the example Weight Vector [1] includes 5 values, it will be appreciated that similar Weight Vectors may include additional values that may be applied to additional measured battery impedances.

In some examples, the weights may be based on a similarity between a currently-measured battery impedance (e.g., the battery impedance measured at operation 404) and the respective previously measured battery impedances. For example, previous battery impedances that are significantly different from the currently-measured battery impedance may have been measured under different, and sometimes significantly different, load conditions. Therefore, such battery impedances may provide less insight into whether the current battery impedance is an outlier. Accordingly, measured battery impedances that are significantly different from the currently-measured battery impedance may be assigned relatively lower weights. Consider, for example, the example Weight Vector [2] given below:

$$WV = [ S\_ 5 , S\_ 4 , S\_ 3 , S\_ 2 , S\_ 1 ] \qquad [ 2 ]$$

In example Weight Vector [2], S_5, S_4, S_3, S_2, S_1 are similarity scores. The similarity scores may indicate a similarity between respective measured battery impedances and the currently-measured battery impedance. The similarity scores may be determined using any suitable techniques such as, for example, cosine similarity, absolute difference, difference, and/or the like.

In some examples, battery impedances may be weighted by combining factors such as, for example, time since measurement and difference from the currently-measured battery impedance. Consider the example Weight Vector [3], which is a combination of the factors described by Weight Vectors [1] and [2]:

$$WV = \underline{[ 1 / 5 * S\_ 5 , 1 / 4 * S\_ 4 , 1 / 3 * S\_ 3 , 1 / 2 * S\_ 2 , 1 / 1 * S\_ 1 ]} \qquad [ 3 ]$$

The result of applying the weights at operation 406 is a set of weighted battery impedances. In examples where the distribution characteristic is a mean or average of the set 114 of measured battery impedances, the mean may be a weighted moving average of measured battery impedances.

At operation 408, the EIS circuit 102 may determine a distribution characteristic of the set of weighted battery impedances. This may be, for example, a mean, a standard deviation, and/or the like as described herein. In examples where the distribution characteristic is a mean or average of the set 114 of measured battery impedances, the mean may be a weighted moving average of measured battery impedances. The set of battery impedances may include the last N battery impedances measured by the EIS circuit, for example, as described herein. In some examples, the EIS circuit 102 may generate two distribution characteristics based on the battery impedance measured at operation 404, for example, as described with respect to FIG. 2. For example, a first distribution characteristic may be based on the real component of the battery impedance measured at operation 404 and a second distribution characteristic may be based on the imaginary component of the battery impedance measured at operation 404.

At operation 408, the EIS circuit 102 may determine if the battery impedance measured at operation 404 is within a threshold of the distribution characteristic of the set of weighted battery impedances determined at operation 406. In examples where the EIS circuit 102 generated a distribution characteristic for the real component and a distribution characteristic for the imaginary component, two comparisons may take place. The first comparison may be between the real component of the battery impedance measured at operation 404 and the real component distribution characteristic. A second comparison may be between the imaginary component of the battery impedance measured at operation 404 and the imaginary component distribution characteristic.

If the battery impedance measured at operation 404 deviates from the distribution characteristic by more than a threshold amount (e.g., if one or both of the real and imaginary component differs from the respective distribution characteristics by more than the respective threshold), then the battery impedance measured at operation 404 is determined to be an outlier. In examples similar to FIG. 2, the battery impedance measured at operation 404 may be considered an outlier if its real component differs from a real component distribution characteristic by more than a threshold or if its imaginary component differs from an imaginary component distribution characteristic by more than a threshold.

If the battery impedance measured at operation 404 is within the threshold of the distribution characteristic measured at operation 406, then, at operation 412, the EIS circuit 103 may store the battery impedance measured at operation 414. At operation 416, the EIS circuit 102 may move to the next frequency and return to operation 402 to apply the excitation signal 124 at the next frequency.

If the battery impedance measured at operation 404 is not within the threshold of the distribution characteristic measured at operation 406, then, at operation 410, the EIS circuit 102 may execute an outlier response. The outlier response may include repeating some or all of the EIS evaluation of the battery 104. In some examples, repeating some or all of the EIS evaluation of the battery 104 includes returning to operation 402 and reapplying the excitation signal at the same frequency. In other examples, repeating some or all of the EIS evaluation of the battery 104 includes remeasuring battery impedances across multiple excitation signal frequencies.

Various examples described herein address the challenges of outlier detection in battery EIS utilizing a stored battery model. The stored battery model may model the response of the battery 104 to different battery conditions such as, for example, load current, excitation signal, temperature, and/or the like. In some examples, use of a trained battery model to detect outliers may provide accurate identification of outliers using a reduced level of processing capacity at the EIS circuit 102.

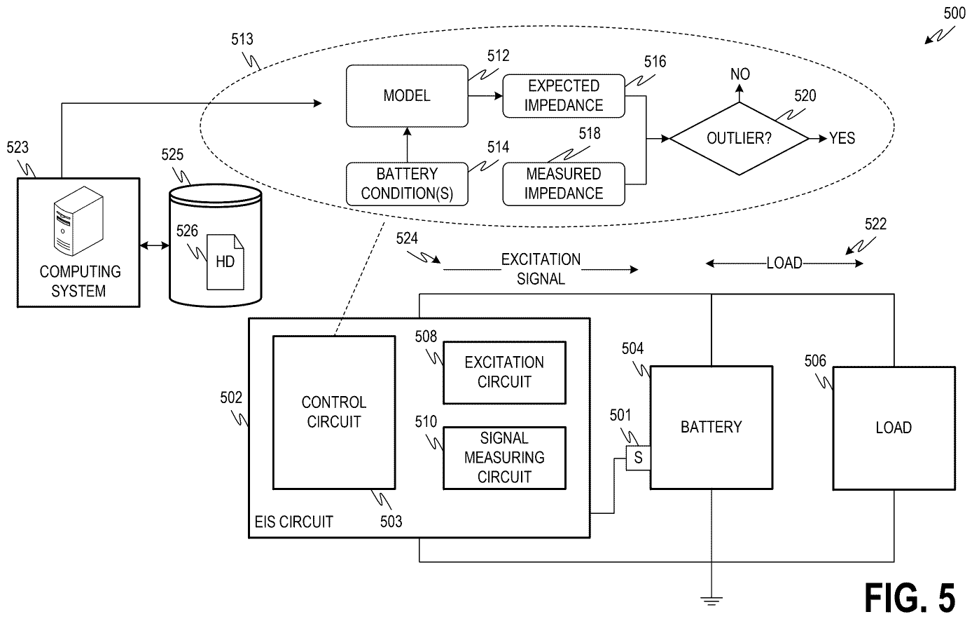

FIG. 5 is a diagram showing an example of the environment 500 comprising an EIS circuit 502, a battery 504, and a load 506, where the EIS circuit 502 is configured to implement outlier detection using a stored model 512. The battery 504 and load 506 may be arranged similar to the battery 104 and load 106 of FIG. 1. For example, the battery 504 and load 506 may share a load current 522 which may be positive or negative, as described herein.

The EIS circuit 502 comprises a control circuit 503, excitation circuit 508, and signal measuring circuit 510 that may operate in a manner similar to that of the control circuit 103, excitation circuit 108, and signal measuring circuit 110 of FIG. 1. For example, the excitation circuit 508 may generate an excitation signal 524, which may be similar to the excitation signal 124 of FIG. 1. The signal measuring circuit 510 may measure a value of the excitation signal 524 to determine one or more impedances of the battery 504.

In the example of FIG. 5, the EIS circuit 502 is in communication with a sensor 501 at the battery 504. The sensor 501 is configured to sense at least one battery property such as, for example, a temperature of the battery. Although a single sensor 501 is shown in FIG. 5, it will be appreciated that multiple sensors may be used. For example, temperature sensors may be deployed at different components of the battery 504 to measured temperatures at different positions in the battery 504.

The stored model 512, in some examples, is generated by the EIS circuit 502. In other examples, the stored model 512 is generated by a remote computing system 523. For example, the remote computing system 523 may store historical data 526 at a data store 525. The historical data 526 may describe the behavior of the battery 504 and/or the behavior of one or more reference batteries. The historical data 526 may be used to generate the stored model 512, for example, as described herein.

The remote computing system 523 may communicate the stored model 512 to the EIS circuit 502, where it may be stored at a memory of the EIS circuit 502 such as, for example, a memory of the control circuit 503. In some examples, the remote computing system 523 may provide the stored model 512 to the EIS circuit 502 during manufacturing. In other examples, the EIS circuit 502 may be in communication with the remote computing system 523 to receive the stored model 512, for example, in situ.

Window 513 shows an example workflow for detecting outliers using the stored model 512. The stored model 512 may be executed by the control circuit 503 using one or more battery conditions 514 as input. The battery conditions 514 may include various conditions of the battery such as, for example, one or more battery temperatures measured by a sensor such as the sensor 501, a current of the excitation signal 524, the load current 522, a voltage drop of the battery 504, a current of the excitation signal 524, a voltage of the excitation signal 524, and/or the like. The control circuit 503 may execute the stored model 512 using the measured battery conditions 514 to generate an expected impedance 516 of the battery 504. The expected impedance 516 may be compared to a measured impedance 518. If, at operation 520, the measured impedance 518 differs from the expected impedance 516 by more than a threshold amount, the measured impedance 518 is determined to be an outlier. If the measured impedance 518 does not differ from the expected impedance 516 by more than the threshold amount, the measured impedance 518 is not determined to be an outlier.

The stored model 512 may be of various different types. In some examples, the stored model is a multivariate regression model. For example, the impedance (e.g., expected impedance 516) of the battery may be considered a dependent variable while the at least one condition of the battery may be considered independent variables. In some examples, a multivariate regression model may have a form similar to that of Equation [4] below:

$$y = {β}_{0} + {β}_{1} {x}_{1} + {β}_{2} {x}_{2} + … + {β}_{n} {x}_{n} \qquad [ 4 ]$$

In Equation [1], y represents the expected impedance 516. The variables x₁, x₂ . . . xₙ represent the of the stored model 512 (e.g., the conditions of the battery). The value n is the number of independent variables/battery conditions considered by the stored model 512. The value β₀ is the intercept and the values β₁, β₂, . . . , βₙ are coefficients of the multivariate regression model.

The multivariate regression model may be trained by finding values for the coefficients. For example, historical data 526 describing the behavior of the battery 104 and/or one or more reference batteries may be collected. For example, the battery 104 and/or one or more reference batteries may be subjected to a range of battery conditions. This may include a range of combinations of battery temperature, load current, excitation signal current, voltage drop, and/or the like. The historical data 526 may describe an impedance of the battery 104 and/or a reference battery under each set of battery conditions. The values of the coefficients may be selected to minimize a difference between the expected impedance 516 (e.g., y) generated by the multivariate regression model and the actual impedance reflected by the historical data. If one or more reference batteries are used to generate the historical data 526, the selected reference battery or batteries may be of a type similar to or identical to that of the battery 504.

The historical data 526 may be used to generate values for the intercept β₀ and the coefficients β₁, β₂, . . . , βₙ of the stored model 512. Any suitable training technique may be used. In some examples, a mean square error (MSE) of a training set of offset and coefficients may be determined by comparing an expected impedance 516 generated using the training set of offset and coefficients to the actual impedance recorded by the historical data 526. A gradient descent or other suitable technique may be used to revise the intercept and coefficients of the stored model 512. Multiple training epochs may be implemented to further refine the intercept and coefficients of the stored model 512.

In some examples, the stored model 512 is an equivalent circuit model (ECM). An ECM represents the behavior of the battery 504 using a network of electrical elements such as, for example, a voltage generator and a combination of passive electrical components such as resistors, capacitors, and inductors, and/or the like. Historical data 526 may be used to determine a form of the ECM and values for the elements making up the ECM. When the measured impedance 518 and corresponding battery conditions 514 are accessed, the control circuit 503 may use battery conditions 514 to select an appropriate ECM, and solve the selected ECM for an impedance value corresponding to the impedance of the battery 504. The determined impedance value may be the expected impedance 516.

In some examples, the stored model 512 may comprise a set of ECMs. Upon receiving the battery conditions 514 and/or in measured impedance 518, the control circuit 103 may be configured to use the battery conditions 514 and/or the measured impedance 518 to select an ECM from a set of ECMs. The control circuit 503 may then use the battery conditions 514 and/or the measured impedance 518 to determine a set of circuit parameters for the selected ECM. The set of circuit parameters may comprise component values for the selected ECM. The control circuit 503 may then use the selected ECM with the selected set of circuit parameters to solve for the expected impedance 516.

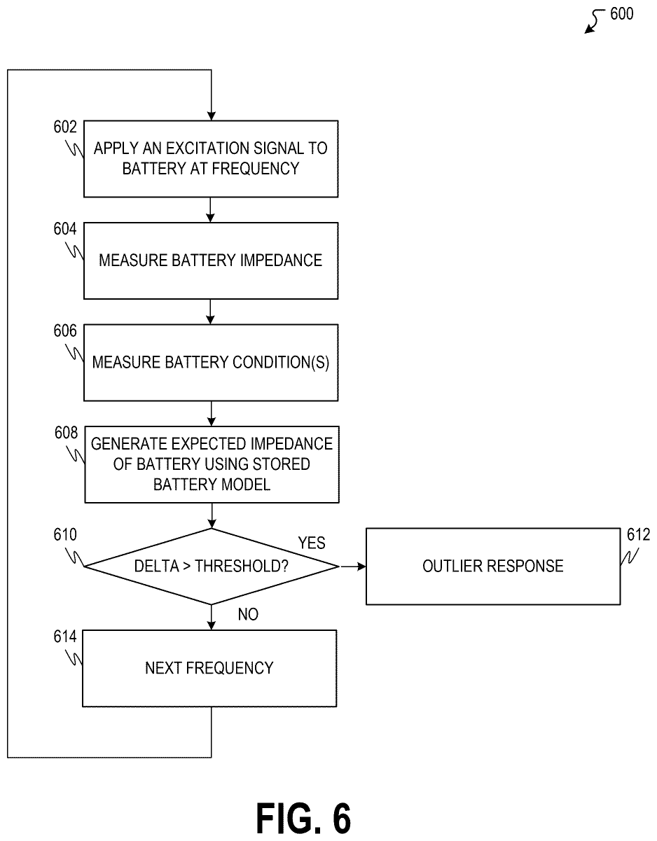

FIG. 6 is a flowchart showing one example of a process flow 600 that may be executed by the EIS circuit 502 in the environment 500 of FIG. 5 to perform an EIS analysis of the battery 504. At operation 602, the EIS circuit 502 may apply the excitation signal 524 to the battery 504 at a first frequency. At operation 604, the EIS circuit 502 may measure the impedance of the battery 504 based on the excitation signal applied at operation 602. This may include, for example, measuring a current of the excitation signal 524 at the first frequency.

At operation 606, the EIS circuit 502 may measure and/or access a set of battery conditions describing the battery 504 at the time that the battery impedance was measured at operation 604. The measured battery conditions may comprise any suitable parameter describing the battery, its condition, and/or its operation. Example battery conditions that may be measured include, for example, the load current 522, which may be positive or negative. In some examples, the measured battery conditions include a cell temperature or temperatures describing a temperature at one or more cells of the battery 504. Other example battery conditions that may be measured are accessed include a current and/or a voltage of the excitation signal 524. In some examples, the EIS circuit 502 may measure one or more of the battery conditions using one or more sensors, such as the sensor 501 and/or other components of the EIS circuit 502 such as, for example, the signal measuring circuit 510 and excitation circuit 508. For example, the signal measuring circuit 510 may measure a current, a voltage, and/or the like of the excitation signal 524. Also, in some examples, the excitation circuit 508 may provide the control circuit 503 with an indication of one or more properties of the excitation signal 524 such as, voltage, current, frequency, and/or the like that may be battery conditions.

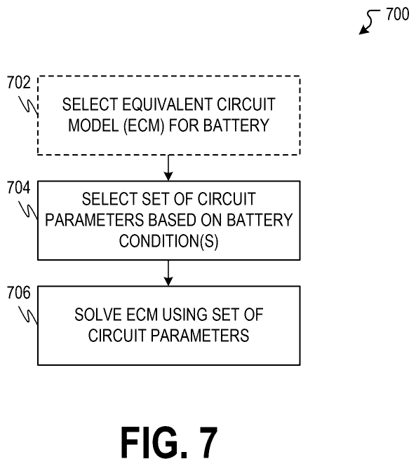

At operation 608, the EIS circuit 502 may generate an expected impedance using the stored model 512. The way that the EIS circuit 502 generates the expected impedance may be different for different types of stored models 512. Consider an example in which the stored model 512 is a multivariate regression model, such as the example provided by Equation [4]. The EIS circuit 502 may access the model including, for example, values for the offset and one or more coefficients. The EIS circuit 502 may solve the stored model 512 using the set of battery conditions as values for the independent variables of the multivariate regression model. The result may be the expected impedance 516. In examples where the stored model is ECMs, the EIS circuit 502 may determine the expected impedance, for example, as described herein with respect to FIG. 7.

At operation 610, the EIS circuit 502 may determine if the battery impedance measured at operation 604 is within a threshold of the expected impedance generated at operation 608. As described herein, the measured impedance and the expected impedance may be complex impedances comprising respective real component and respective imaginary component. In some examples, the EIS circuit 502 may find a vector difference between the expected impedance and the measured impedance considering both the respective real components and imaginary components. Also, in some examples, the EIS circuit 502 may determine a first difference between the respective real components of the expected impedance and the measured impedance and a second difference between the respective imaginary component of the measured impedance and the expected impedance.

If the battery impedance measured at operation 604 deviates from the expected impedance by more than a threshold amount, then the battery impedance measured at operation 604 is determined to be an outlier. In some examples, the threshold may be between about 1% and about 10%. In some examples, the threshold amount may be based on a distribution of battery impedance measurements used to generate the expected battery impedance. For example, the currently measured impedance may be considered an outlier if it deviates from the expected impedance by more than a multiple of standard deviations of the distribution such as, for example, 1, 2, 3, 4, 5, or another multiple of standard deviations.

If the battery impedance measured at operation 604 is within the threshold of the expected impedance at operation 610 then, at operation 614, the EIS circuit 502 may move to the next frequency and return to operation 602 to apply the excitation signal 524 at the next frequency. If the battery impedance measured at operation 604 is not within the threshold of the at operation 610 then, at operation 612, the EIS circuit 502 may execute an outlier response. The outlier response may include repeating some or all of the EIS evaluation of the battery 504. In some examples, repeating some or all of the EIS evaluation of the battery 504 includes returning to operation 602 and reapplying the excitation signal at the same frequency. In some examples, repeating some or all of the EIS evaluation of the battery 504 includes remeasuring battery impedances across multiple excitation signal frequencies.

FIG. 7 is a flowchart showing one example of a process flow 700 that may be executed by the EIS circuit 502 to determine an expected impedance using an ECM. For example, the process flow 700 illustrates one example way the EIS circuit 502 may execute the operation 608 of the process flow 600.

At operation 702, the EIS circuit 502 may select an ECM using one or more battery conditions measured and/or accessed at operation 606. For example, the stored model 512 may comprise multiple different ECM topologies, with each ECM topology corresponding to a range of values of the set of battery conditions. The EIS circuit 502 may select the ECM corresponding to the set of battery conditions. Data describing the ECM's making up the stored model 512 may be stored, for example, at a memory of the control circuit 503. In some examples, the stored model 512 may comprise only a single ECM that is used across different sets of battery conditions. In these examples, the operation 702 may be omitted.

At operation 704, the EIS circuit 502 may a set of circuit parameters for the selected ECM based on the battery conditions. In some examples, the EIS circuit 502 may store, for example, at a memory of the control circuit 503, a lookup table or other data structure comprising ECM circuit parameters corresponding to different battery conditions or ranges of battery conditions. At operation 706, the EIS circuit 502 may solve the ECM using the set of circuit parameters. Solving the ECM may include determining in impedance of the battery 504 for the ECM given the circuit parameters selected at operation 704.

Various examples described herein address the challenges of outlier detection in battery EIS utilizing a stored battery model based on a multidimensional probability distribution, such as a multivariate Gaussian distribution. The multidimensional probability distribution may comprise dimensions corresponding to conditions of the battery and/or battery impedance. When a new measured battery impedance is received, the EIS circuit may use the new measured battery impedance and at least one battery condition at the time of the new measured battery impedance. The EIS circuit may compare a multidimensional vector comprising the new measured battery impedance and one or more measured battery conditions to the multidimensional probability distribution. The EIS circuit may determine whether the new measured battery impedance is an outlier based on the comparison.

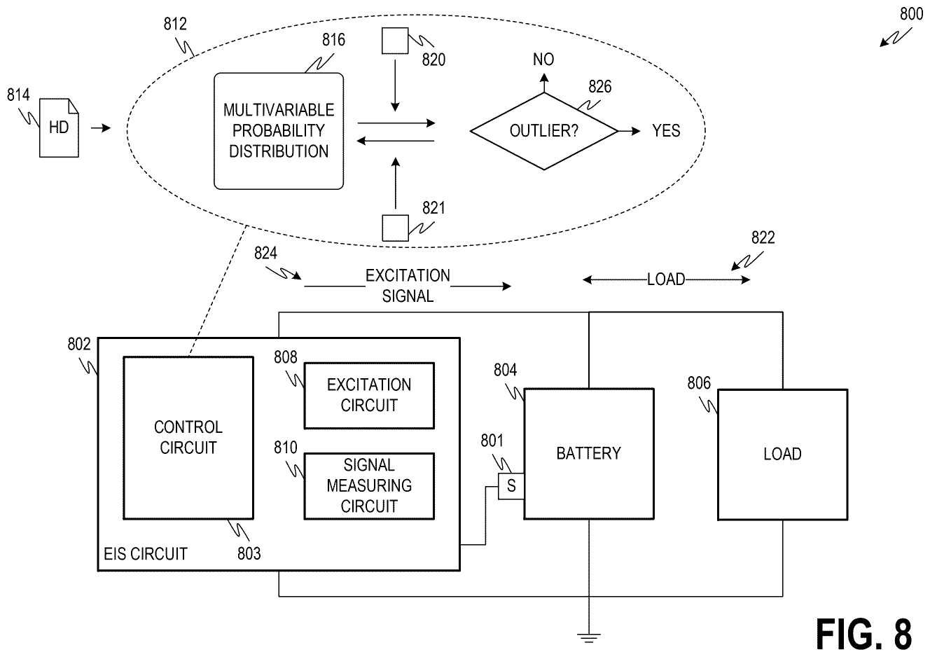

FIG. 8 is a diagram showing an example of the environment 800 comprising an EIS circuit 802, a battery 804, and a load 806, where the EIS circuit 802 is configured to implement outlier detection using a multivariable probability distribution 816. The battery 804 and load 806 may be arranged similar to the battery 104 and load 106 of FIG. 1. For example, the battery 804 and load 806 may share a load current 822 which may be positive or negative, as described herein.

The EIS circuit 802 comprises a control circuit 803, excitation circuit 808, and signal measuring circuit 810 that may operate in a manner similar to that of the control circuit 103, excitation circuit 108, and signal measuring circuit 110 of FIG. 1. For example, the excitation circuit 808 may generate an excitation signal 824, which may be similar to the excitation signal 124 of FIG. 1. The signal measuring circuit 810 may measure a value of the excitation signal 824 to determine one or more impedances of the battery 804.

In the example of FIG. 8, the EIS circuit 802 is in communication with a sensor 801 at the battery 804. The sensor 801 is configured to sense at least one battery property such as, for example, a temperature of the battery. Although a single sensor 801 is shown in FIG. 8, it will be appreciated that multiple sensors may be used. For example, temperature sensors may be deployed at different components of the battery 804 to measured temperatures at different positions in the battery 804.

A window 812 shows an example workflow for detecting outliers using the multivariable probability distribution 816. The multivariable probability distribution 816 may be generated utilizing historical data 814. The historical data 814 may describe previously-measured battery impedances and battery conditions at the time of the previously-measured battery impedances. For example, battery impedance and the respective battery conditions may make up dimensions of the multivariable probability distribution. In some examples, each set of a measured battery impedance and the battery conditions at the time of the measured battery impedance may be represented as vectors. An example vector is given by Equation [5] below:

$$X = {[ {X}_{1} … {X}_{n} ]}^{T} \qquad [ 5 ]$$

In Equation [2], X is a vector described by dimensions X₁ . . . . Xₙ. One or more of the dimensions X₁ . . . . Xₙ may represent a measured battery impedance. In some examples, a real component and an imaginary component of the battery impedance are represented as distinct dimensions in the vector X. The other dimension or dimensions X₁ . . . . Xₙ may represent battery conditions when the measured battery impedance was taken. In some examples, at least one dimension Xₙ of the vector X may be based on the state of the excitation signal 824 such as, for example, a current of the excitation signal 824 and/or a voltage of the excitation signal 824. The historical data 814 may describe a number of vectors made up of measured battery impedances and associated battery conditions, for example, of the form described by Equation [5]. The multivariable probability distribution 816 may be a distribution based on the factors described by the historical data 814.

The EIS circuit 802 may measure a battery impedance 820 of the battery 804. The EIS circuit 802 may also measure and/or access indications of at least one condition 821 of the battery at or about the same time that the battery impedance 820 was measured. The battery impedance 820 and at least one condition 821 may be compared to the multivariable probability distribution 816. For example, the EIS circuit 802 may determine a multidimensional vector with dimensions corresponding to the battery impedance 820 and battery conditions of the at least one condition 821, for example, according to the form described by Equation [5]. The vector may be compared to the multivariable probability distribution 816. If, at operation 826, the difference between the vector and the multivariable probability distribution 816 is greater than a threshold, then the battery impedance 820 is determined to be an outlier. If the difference between the vector and the multivariable probability distribution 816 is not greater than the threshold, then the battery impedance 820 may not be considered an outlier.

In some examples, the battery impedance 820 and at least one condition 821 are also used to update the multivariable probability distribution 816. For example, the EIS circuit 802 may recalculate one or more characteristics of the multivariable probability distribution 816 considering the battery impedance 820 and the at least one condition 821. The recalculated multivariate probability distribution 816 may be used for future impedance measurements of the battery 804.

In some examples, the multivariable probability distribution 816 may be a multivariate Gaussian distribution. A multivariate Gaussian distribution may be described by Equation [6] below:

$$p ( x ; μ , \sum ) = \frac{1}{{( 2 π )}^{n / 2} {\vert \sum \vert}^{1 / 2}} exp ( - \frac{1}{2} {( x - μ )}^{T} {\sum }^{- 1} ( x - μ ) ) \qquad [ 6 ]$$

In Equation [6], x represents dimensions of the vectors making up the distribution. The vector u is the a mean vector, where the dimensions of the mean vector correspond to the means of the various dimensions across all of the vectors described by the multivariate Gaussian distribution. The matrix 2 is a covariance matrix describing the distribution.

In some examples, the EIS circuit may compare a vector describing a new measured battery impedance 820 and one or more battery conditions 821 to the multivariable probability distribution 816 by finding a vector distance between the mean vector u and the vector derived from the battery impedance 820 and one or more battery conditions 821. Also, in some examples, the threshold distance between the mean vector u and the vector derived from the battery impedance 820 and one or more battery conditions 821 may be based on the covariance matrix 2.

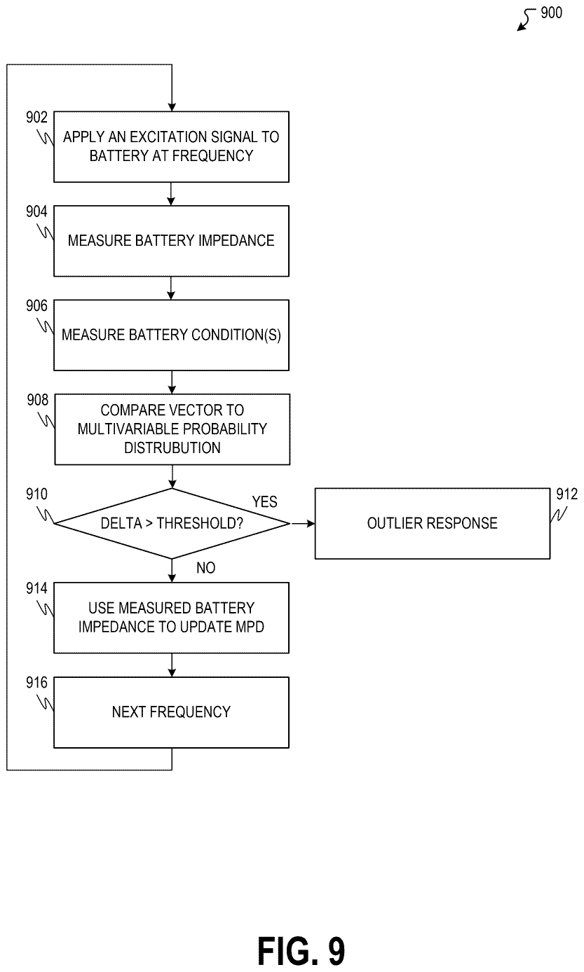

FIG. 9 is a flowchart showing one example of a process flow 900 that may be executed by the EIS circuit 802 in the environment 800 of FIG. 8 to perform an EIS analysis of the battery 804. At operation 902, the EIS circuit 802 may apply the excitation signal 824 to the battery 804 at a first frequency. At operation 904, the EIS circuit 802 may measure the impedance of the battery 804 based on the excitation signal applied at operation 902. This may include, for example, measuring a current of the excitation signal 824 at the first frequency.

At operation 906, the EIS circuit 802 may measure and/or access a set of battery conditions describing the battery 804 at the time that the battery impedance was measured at operation 904. The measured battery conditions may comprise any suitable parameter describing the battery, its condition, and/or its operation. Example battery conditions that may be measured include, for example, the load current 822, which may be positive or negative. In some examples, the measured battery conditions include a cell temperature or temperatures describing a temperature at one or more cells of the battery 804. Other example battery conditions that may be measured are accessed include a current and/or a voltage of the excitation signal 824. In some examples, the EIS circuit 802 may measure one or more of the battery conditions using one or more sensors, such as the sensor 801 and/or other components of the EIS circuit 802 such as, for example, the signal measuring circuit 810 and excitation circuit 808. For example, the signal measuring circuit 810 may measure a current, a voltage, and/or the like of the excitation signal 824. Also, in some examples, the excitation circuit 808 may provide the control circuit 803 with an indication of one or more properties of the excitation signal 824 such as, voltage, current, frequency, and/or the like that may be battery conditions.

At operation 908, the EIS circuit 802 may compare the battery impedance measured at operation 904 and the one or more battery conditions measured at operation 906 to the multivariable probability distribution 816. In some examples, as described herein, the EIS circuit 802 may determine a multivariable probability distribution on the battery impedance measured at operation 904 and the one or more battery conditions measured at operation 906. The EIS circuit 802 may find a distance between the vector and a mean vector of the multivariable probability distribution 816.

At operation 910, the EIS circuit 802 determines if the difference between the battery impedance/battery condition(s) and the multivariable probability distribution 816 is greater than a threshold. If yes, the battery impedance measured at operation 904 is determined to be an outlier. If no, then the battery impedance measured at operation 904 may not be an outlier.

If the battery impedance measured at operation 904 is not an outlier then, at operation 914, the EIS circuit 802 may use the battery impedance measured at operation 904 to update the multivariable probability distribution 816. For example, the vector generated from the measured battery impedance and the at least one battery condition may be added to the vectors described by the multivariable probability distributional 816. New characteristics of the multibeam a probability distribution, including the new measurement, may be determined. The determined new characteristics may be utilized for detecting outliers from future battery impedance measurements.

If the battery impedance measured at operation 904 is an outlier then, at operation 912, the EIS circuit 802 may execute an outlier response. The outlier response may include repeating some or all of the EIS evaluation of the battery 804. In some examples, repeating some or all of the EIS evaluation of the battery 804 includes returning to operation 902 and reapplying the excitation signal at the same frequency. In some examples, repeating some or all of the EIS evaluation of the battery 804 includes remeasuring battery impedances across multiple excitation signal frequencies. Also, although the operation 914 is shown to be executed only for measured battery impedances that are not outliers, in some examples, measured battery impedances that are outliers may also be used to update the multivariable probability distribution 816. At operation 916, the EIS circuit 802 may move to the next frequency and return to operation 902 to apply the excitation signal 824 at the next frequency.

In some examples, the EIS circuit 802 is configured to generate and update the multivariable probability distribution 816, for example, as shown in FIG. 8. In other examples, the EIS circuit 802 is in communication with a remote computing system that determines and/or update the multivariable probability distribution 816 and provides the multivariable probability distribution 816 to the EIS circuit 802.

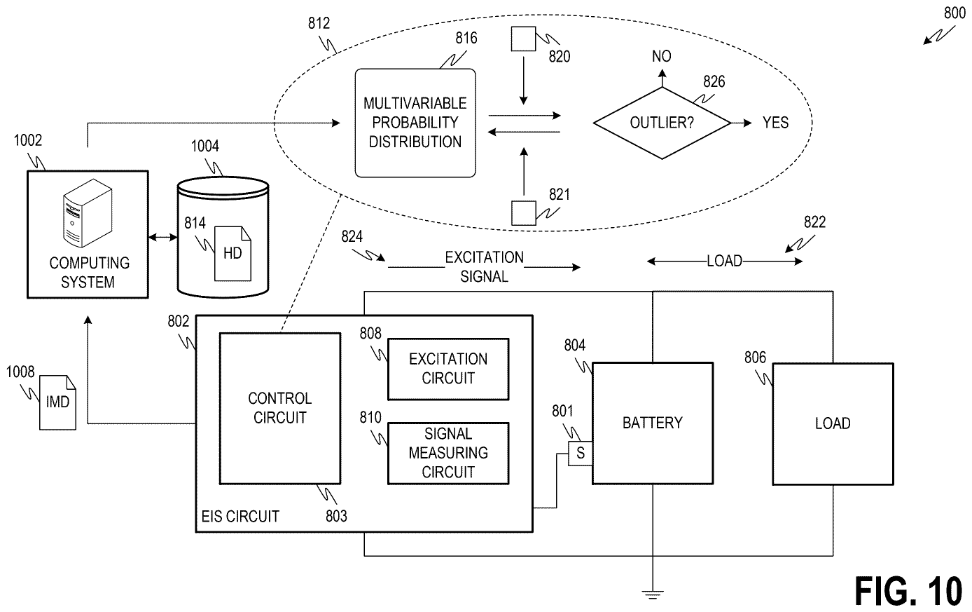

FIG. 10 is a diagram showing another example of the environment 800 with the EIS circuit 802 in communication with a remote computing system 1002. The remote computing system 1002 may be any suitable computing device or devices such as, for example, a server computing system, a laptop computer, a desktop computer, a tablet computer, and/or the like. In some examples, the computing system 1002 is implemented using a cloud service provider. The EIS circuit 802 may communicate with the remote computing system 1002 using any suitable communication medium such as, for example, a wired network, a wireless network, a mixed wired and wireless network, and/or the like.

The EIS circuit 802 may provide impedance measurement data 1008 to the remote computing system 1002. The impedance measurement data 1008 may describe battery impedance measurements made by the EIS circuit 802. For example, the impedance measurement data 1008 may include measured battery impedances as well as indications of at least one battery condition at the time that the battery impedance was measured. In some examples, the EIS circuit 802 may send impedance measurement data 1008 instead of updating the multivariable probability distribution 816 in situ. For example, the operation 914 of a process flow 900 may be omitted and, instead, the EIS circuit 802 may send impedance measurement data 1008 describing the measured battery impedance and a corresponding battery conditions to the remote computing system 1002.

The remote computing system 1002 may aggregate received impedance measurement data 1008 to generate historical data 814. The historical data 814 may be stored at a data store 1004 associated with the remote computing system 1002. The remote computing system 1002 may utilize the historical data 814 to generate the multivariable probability distribution 816. The remote computing system 1002 may provide the multivariable probability distribution 816, and/or updates thereto, to the EIS circuit 802.

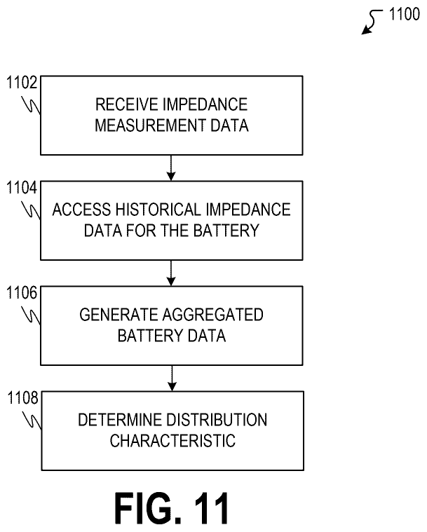

FIG. 11 is a flowchart showing one example of a process flow 1100 that may be executed by the EIS circuit 802 and/or the remote computing system 1002 to generate the multivariable probability distribution 816. At operation 1102, the system (e.g. the EIS circuit 802 and/or remote computing system 1002) may receive impedance measurement data. If the process flow 1100 is being executed by the EIS circuit 802, this may include measuring the impedance of the battery and/or one or more concurrent battery conditions, as described herein. In examples where the process flow 1100 is executed by the remote computing system 1002, this may include receiving impedance measurement data 1008 from the EIS circuit 802. In some examples, the EIS circuit 802 may send impedance measurement data 1008 after every impedance measurement and/or may batch multiple impedance measurements and send impedance measurement data 1008 describing multiple impedance measurements.

At operation 1104, the implementing system may access historical data 814 describing the battery 804. At operation 1106, the implementing system may generate aggregated battery data using the historical data 814 and the impedance measurement data 1008. At operation 1108, the implementing system may determine one or more multivariable probability distribution characteristics using the aggregate data. These may include, for example, a mean vector and/or a variance matrix as described herein. In examples where the process flow 1100 is executed by the remote computing system 1002, the remote computing system 1002 may send the at least one distribution characteristic determined at 1108 to the EIS circuit 802 to represent the multivariable probability distribution 816.

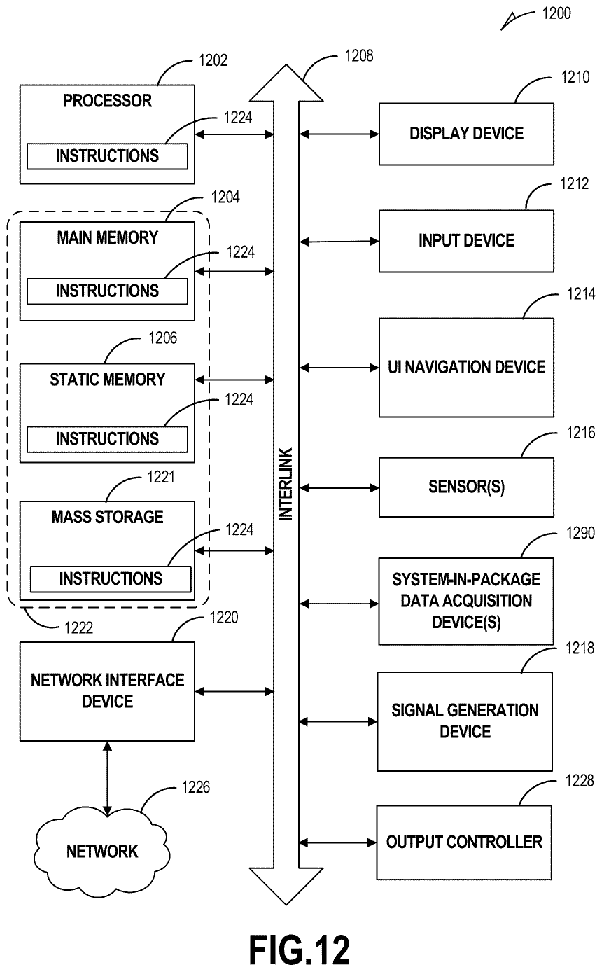

FIG. 12 is a block diagram of an example machine 1200 upon which any one or more of the techniques (e.g., methodologies) discussed herein may be performed. In alternative examples, the machine 1200 may operate as a standalone device or may be connected (e.g., networked) to other machines. In a networked deployment, the machine 1200 may operate in the capacity of a server machine, a client machine, or both in server-client network environments. In an example, the machine 1200 may act as a peer machine in a peer-to-peer (P2P) (or other distributed) network environment. The machine 1200 may be a personal computer (PC), a tablet PC, a set-top box (STB), a personal digital assistant (PDA), a mobile telephone, a web appliance, an IoT device, an automotive system, an aerospace system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, by moveable placement of invariant-massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1200 may include a hardware processing unit 1202 (e.g., a central processing unit (CPU), a graphics processing unit (GPU), a hardware processor core, or any combination thereof, such as a memory controller, etc.), a main memory 1204, and a static memory 1206, some or all of which may communicate with each other via an interlink (e.g., bus) 1208. The machine 1200 may further include a display device 1210, an alphanumeric input device 1212 (e.g., a keyboard), and a user interface (UI) navigation device 1214 (e.g., a mouse). In an example, the display device 1210, alphanumeric input device 1212, and UI navigation device 1214 may be a touchscreen display. The machine 1200 may additionally include a storage device 1222 (e.g., drive unit); a signal generation device 1218 (e.g., a speaker); a network interface device 1220; one or more sensors 1216, such as a Global Positioning System (GPS) sensor, wing sensor, mechanical device sensor, temperature sensor, bridge sensor, audio sensor, industrial sensor, a compass, an accelerometer, or other sensors; and one or more system-in-package data acquisition devices 1290. The system-in-package data acquisition device(s) 1290 may implement some or all of the functionality of the electrolyzer systems, discussed above. The machine 1200 may include an output controller 1228, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The storage device 1222 may include a machine-readable medium on which is stored one or more sets of data structures or instructions 1224 (e.g., software) embodying or utilized by any one or more of the techniques or functions described herein. The instructions 1224 may also reside, completely or at least partially, within the main memory 1204, within the static memory 1206, or within the hardware processing unit 1202 during execution thereof by the machine 1200. In an example, one or any combination of the hardware processing unit 1202, the main memory 1204, the static memory 1206, or the storage device 1222 may constitute the machine-readable medium.

While the machine-readable medium is illustrated as a single medium, the term “machine-readable medium” may include a single medium or multiple media (e.g., a centralized or distributed database, or associated caches and servers) configured to store the one or more instructions 1224.

The term “machine-readable medium” may include any transitory or non-transitory medium that is capable of storing, encoding, or carrying transitory or non-transitory instructions for execution by the machine 1200 and that cause the machine 1200 to perform any one or more of the techniques of the present disclosure, or that is capable of storing, encoding, or carrying data structures used by or associated with such instructions. Non-limiting machine-readable medium examples may include solid-state memories and optical and magnetic media. In an example, a massed machine-readable medium comprises a machine-readable medium with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1224 (e.g., software, programs, an operating system (OS), etc.) or other data that are stored on the storage device 1221 can be accessed by the main memory 1204 for use by the hardware processing unit 1202. The main memory 1204 (e.g., DRAM) is typically fast, but volatile, and thus a different type of storage from the storage device 1221 (e.g., an SSD), which is suitable for long-term storage, including while in an “off” condition. The instructions 1224 or data in use by a user or the machine 1200 are typically loaded in the main memory 1204 for use by the hardware processing unit 1202. When the main memory 1204 is full, virtual space from the storage device 1221 can be allocated to supplement the main memory 1204; however, because the storage device 1221 is typically slower than the main memory 1204, and write speeds are typically at least twice as slow as read speeds, use of virtual memory can greatly reduce user experience due to storage device latency (in contrast to the main memory 1204, e.g., DRAM). Further, use of the storage device 1221 for virtual memory can greatly reduce the usable lifespan of the storage device 1221.

The instructions 1224 may further be transmitted or received over a communications network 1226 using a transmission medium via the network interface device 1220 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone Service (POTS) networks, and wireless data networks (e.g., Institute of Electrical and Electronics Engineers (IEEE) 802.11 family of standards known as Wi-Fi®, IEEE 802.16 family of standards known as WiMax®, IEEE 802.15.4 family of standards, P2P networks), among others. In an example, the network interface device 1220 may include one or more physical jacks (e.g., Ethernet, coaxial, or phone jacks) or one or more antennas to connect to the communications network 1226. In an example, the network interface device 1220 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible or intangible medium that is capable of storing, encoding, or carrying instructions for execution by the machine 1200, and includes digital or analog communications signals or other tangible or intangible media to facilitate communication of such software.

Each of the non-limiting examples or examples described herein may stand on its own, or may be combined in various permutations or combinations with one or more of the other examples.

The above detailed description includes references to the accompanying drawings, which form a part of the detailed description. The drawings show, by way of illustration, specific examples in which the inventive subject matter may be practiced. These examples are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more examples thereof), either with respect to a particular example (or one or more examples thereof), or with respect to other examples (or one or more examples thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following examples, the terms “including” and “comprising” are open-ended; that is, a system, device, article, composition, formulation, or process that includes elements in addition to those listed after such a term in an aspect are still deemed to fall within the scope of that aspect. Moreover, in the following examples, the terms “first,” “second,” “third,” and so forth are used merely as labels and are not intended to impose numerical requirements on their objects.

Method examples described herein may be machine- or computer-implemented at least in part. Some examples may include a computer-readable medium or machine-readable medium encoded with transitory or non-transitory instructions operable to configure an electronic device to perform methods as described in the above examples. An implementation of such methods may include code, such as microcode, assembly-language code, a higher-level-language code, or the like. Such code may include transitory or non-transitory computer-readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read-only memories (ROMs), and the like.

The above description is intended to be illustrative, and not restrictive. For example, the above-described examples (or one or more examples thereof) may be used in combination with each other. Other examples may be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above detailed description, various features may be grouped together to streamline the disclosure. This should not be interpreted as intending that a disclosed feature not listed in the list of claims is essential to any aspect. Rather, inventive subject matter may lie in less than all features of a particular disclosed example. Thus, the following examples are hereby incorporated into the detailed description as examples or examples, with each claim standing on its own as a separate example, and it is contemplated that such examples may be combined with each other in various combinations or permutations. The scope of the inventive subject matter should be determined with reference to the appended claims, along with the full scope of equivalents to which such claims are entitled.

1. An Electrochemical Impedance Spectroscopy (EIS) circuit comprising:
an excitation circuit for generating an alternating current (AC) excitation signal; and
a control circuit configured to perform operations comprising:
applying an alternating current (AC) excitation signal to a battery at a first time while the battery is also under a load;
measuring a first impedance of the battery at a first time;
determining at least one condition of the battery at the first time, the at least one condition comprising a load current of the battery;
generating an expected impedance of the battery at the first time using a stored battery model and the at least one condition of the battery at the first time;
determining that the first impedance of the battery is an outlier, the determining based on a difference between the first impedance of the battery and the expected impedance of the battery; and
based on determining that the first impedance is an outlier, measuring an additional impedance of the battery.

2. The EIS circuit of claim 1, the load current being a positive load current provided by the battery to the load.

3. The EIS circuit of claim 1, the load current being a negative load current provided to the battery by the load.

4. The EIS circuit of claim 1, the at least one condition further comprising a cell temperature.

5. The EIS circuit of claim 1, the stored battery model comprising a regression model generated using at least one reference battery different than the battery, the generating of the expected impedance comprising executing the regression model using the at least one condition of the battery at the first time.

6. The EIS circuit of claim 1, the stored battery model comprising an equivalent circuit model (ECM), the generating of the expected impedance comprising solving the ECM using the at least one condition at the battery of the first time.

7. The EIS circuit of claim 1, the stored battery model comprising an equivalent circuit model (ECM), the generating of the expected impedance comprising:
accessing equivalent circuit parameter data, the equivalent circuit parameter data describing a set of circuit parameters corresponding to the at least one condition of the battery at the first time; and
generating the expected impedance of the battery at the first time at least in part by applying the set of circuit parameters to the ECM.

8. The EIS circuit of claim 1, the generating of the expected impedance comprising:
using the at least one condition of the battery at the first time to select an ECM from a set of ECMs;
using the at least one condition of the battery to select a set of circuit parameters; and
generating the expected impedance of the battery at the first time at least in part by applying the set of circuit parameters to the selected ECM.

9. A method of analyzing a battery comprising:
applying an alternating current (AC) excitation signal to a battery at a first time while the battery is also under a load;
measuring a first impedance of the battery at a first time;
determining at least one condition of the battery at the first time, the at least one condition comprising a load current of the battery;
generating an expected impedance of the battery at the first time using a stored battery model and the at least one condition of the battery at the first time;
determining that the first impedance of the battery is an outlier, the determining based on a difference between the first impedance of the battery and the expected impedance of the battery; and
based on determining that the first impedance is an outlier, measuring an additional impedance of the battery.

10. The method of claim 9, the load current being a positive load current provided by the battery to the load.

11. The method of claim 9, the load current being a negative load current provided to the battery by the load.

12. The method of claim 9, the at least one condition further comprising a cell temperature.

13. The method of claim 9, the stored battery model comprising a regression model generated using at least one reference battery different than the battery, the generating of the expected impedance comprising executing the regression model using the at least one condition of the battery at the first time.

14. The method of claim 9, the stored battery model comprising an equivalent circuit model (ECM), the generating of the expected impedance comprising solving the ECM using the at least one condition at the battery of the first time.

15. The method of claim 9, the stored battery model comprising an equivalent circuit model (ECM), the generating of the expected impedance comprising:
accessing equivalent circuit parameter data, the equivalent circuit parameter data describing a set of circuit parameters corresponding to the at least one condition of the battery at the first time; and
generating the expected impedance of the battery at the first time at least in part by applying the set of circuit parameters to the ECM.

16. The method of claim 9, the generating of the expected impedance comprising:
using the at least one condition of the battery at the first time to select an ECM from a set of ECMs;
using the at least one condition of the battery to select a set of circuit parameters; and
generating the expected impedance of the battery at the first time at least in part by applying the set of circuit parameters to the selected ECM.

17. A non-transitory computer-readable medium comprising instructions thereon that, when executed by at least one processor, cause the at least one processor to perform operations comprising:
applying an alternating current (AC) excitation signal to a battery at a first time while the battery is also under a load;
measuring a first impedance of the battery at a first time;
determining at least one condition of the battery at the first time, the at least one condition comprising a load current of the battery;
generating an expected impedance of the battery at the first time using a stored battery model and the at least one condition of the battery at the first time;
determining that the first impedance of the battery is an outlier, the determining based on a difference between the first impedance of the battery and the expected impedance of the battery; and
based on determining that the first impedance is an outlier, measuring an additional impedance of the battery.

18. The non-transitory computer-readable medium of claim 17, the load current being a positive load current provided by the battery to the load.

19. The non-transitory computer-readable medium of claim 17, the load current being a negative load current provided to the battery by the load.

20. The non-transitory computer-readable medium of claim 17, the at least one condition further comprising a cell temperature.
